(19) United States
(12) Patent Application Publication
(10) Pub. No.: US 2008/0296725 A1
(43) Pub. Date: Dec. 4, 2008

(54) SEMICONDUCTOR COMPONENT AND METHOD FOR FABRICATING THE SAME

(75) Inventors: Ching-Nan Hsiao, Kaohsiung County (TW); Chung-Lin Huang, Taoyuan County (TW); Chen-Yu Tsai, Taipei County (TW); Chung-Yuan Lee, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/955,399

(22) Filed: Dec. 13, 2007

(30) Foreign Application Priority Data
May 28, 2007 (TW) 96118909

(51) Int. Cl. H01L 23/00; H01L 21/76

(52) U.S. Cl. 257/508; 438/404; 257/E21.54; 257/E23.001

(57) ABSTRACT

A semiconductor component includes a substrate, two isolation structures, a conductor pattern and a dielectric layer. The isolation structures are disposed in the substrate, and each of the isolation structures has protruding portions protruding from the surface of the substrate. A trench is formed between the protruding portions. The included angle formed by the sidewall of the protruding portion and the surface of the substrate is an obtuse angle. The conductor pattern is disposed in the trench and fills the trench up. The dielectric layer is disposed between the conductor pattern and the substrate.

### CROSS-REFERENCE TO RELATED APPLICATION

This application claims the priority benefit of Taiwan application serial no. 96118909, filed on May 28, 2007. The entirety of the above-mentioned patent application is hereby incorporated by reference herein and made a part of this specification.

### BACKGROUND OF THE INVENTION

1. Field of the Invention

The present invention relates to a semiconductor component and, more particularly to a semiconductor component and a method for fabricating the same.

2. Description of Related Art

In semiconductor device fabrication process, the quality of isolation structures can have a significant influence on the electrical performance of semiconductor components. However, currently there are still some problems that need to be overcome when forming isolation structures. A floating gate structure that forms a flash memory device is used as an example in the following description.

A flash memory device is a non-volatile memory that allows multiple data writing, reading and erasing operations. In addition, the information stored in the memory will be maintained even after power to the device is off. Therefore, the non-volatile memory device has been widely used in personal computers and many other electronic equipment.

A typical flash memory has a floating gate and a control gate fabricated using doped polysilicon. Herein, the floating gate is disposed between the control gate and the substrate, and in a floating state that is not electrically connected to any circuit. Further, the control gate is electrically connected to the word line. In addition, a tunneling oxide layer is disposed between the substrate and the floating gate while an inter-gate dielectric layer is disposed between the floating gate and the control gate. When the memory is being programmed, the floating gate is used to hold the charges that were injected onto the floating gate.

FIGS. 1A through 1C are schematic cross-sectional views illustrating the steps for fabricating a conventional floating gate structure.

Referring to FIG. 1A, a tunneling dielectric layer 102, a polysilicon floating gate material layer 104, and a silicon nitride mask layer 106 are sequentially formed on a substrate 100.

Referring to FIG. 1B, a trench 108 is formed extending through the tunneling dielectric layer 102, the polysilicon floating gate material layer 104, and the silicon nitride mask layer 106 and into the substrate 100. Simultaneously, the polysilicon floating gate material layer 104 is defined as a striped floating gate pattern 110. Thereafter, an isolation structure material layer 112 is filled in the trench 108.

Referring to FIG. 1C, a wet etching process is used to remove the silicon nitride mask layer 106. Further, a chemical mechanical polishing process is performed to the isolation structure material layer 112 to form an isolation structure 114 and the floating gate pattern 110 is used as the stop layer. Herein, an angle θ₁ formed between the sidewall of the isolation structure 114 and the bottom surface of the floating gate pattern 110 is an acute angle.

The following description refers to FIGS. 1A through 1C.

Since an active area is defined when the trench 108 is formed, the pattern of the floating gate pattern 110 must be simultaneously defined. Hence, the portion to be etched to form the trench 108 includes not only the substrate 100, but also the tunneling dielectric layer 102, the polysilicon floating gate material layer 104, and the silicon nitride mask layer 106. Therefore, it is not easy to etch the depth desired for the trench 108 because the required depth is rather deep.

Further, due to the depth of the trench 108 is fairly deep, the gap-filling of the isolation structure material layer 112 in the trench 108 is thus poor and defects like holes are formed in the isolation structure 114.

On the other hand, since the angle θ₁ formed by the sidewall of the isolation structure 114 and the bottom surface of the floating gate pattern 110 is an acute angle, polysilicion residues are generated when defining the striped floating gate pattern 110 as a block floating gate. As a result, a short circuit occurs between two adjacent block floating gates.

### SUMMARY OF THE INVENTION

Accordingly, the present invention is directed to a semiconductor component that prevents the occurrence of a short circuit between two adjacent floating gates.

Further, the present invention is also directed to a method for fabricating a semiconductor component that can effectively simplify the fabrication process of the semiconductor component.

The present invention is directed to a semiconductor component including a substrate, two isolation structures, a conductor pattern, and a dielectric layer. The isolation structures are disposed in the substrate. Further, each of the isolation structures has protruding portions protruding from the surface of the substrate. In addition, a trench is formed between the protruding portions and an angle formed between a sidewall of a respective one of the protruding portions and the surface of the substrate is an obtuse angle. The conductor pattern is then disposed in the trench.

According to one embodiment of the invention, the substrate in the aforementioned semiconductor component includes a silicon substrate.

According to one embodiment of the present invention, the material used for fabricating the isolation structure in the aforementioned semiconductor component includes silicon oxide.

According to one embodiment of the present invention, the material used for fabricating the conductor pattern in the aforementioned semiconductor component includes polysilicon.

According to one embodiment of the present invention, the aforementioned semiconductor component further includes a dielectric layer disposed between the conductor pattern and the substrate.

The present invention is directed to a method for fabricating a semiconductor component that includes the following steps. First, two isolation structures are formed in a substrate. Further, each of the isolation structures has protruding portions protruding from the surface of the substrate. In addition, a first trench is formed between the protruding portions and the angle formed between the sidewall of the protruding portion and the surface of the substrate is an acute angle. Next, a profile adjustment process is performed to the protruding portion to modify the angle formed between the sidewall of the protruding portion and the surface of the substrate to an obtuse angle. Afterwards, a conductor pattern is formed on the substrate and fills the first trench.

According to one embodiment of the present invention, in the method for forming the aforementioned semiconductor component, the method for forming the isolation structure includes the following steps. First, a mask layer is formed on the substrate. Next, two second trenches are formed in the substrate and the mask layer. Thereafter, an isolation structure material layer is formed on the mask layer and fills the second trenches. Afterward, the portion of the isolation structure material layer excluding the second trenches is removed. Subsequently, the mask layer is removed.

According to one embodiment of the invention, the method for forming the aforementioned semiconductor component further includes forming a dielectric layer on the portion of the substrate exposed by the first trench.

According to one embodiment of the present invention, in the method for forming the aforementioned semiconductor component, the method for forming the mask layer includes a chemical vapor deposition process.

According to one embodiment of the present invention, in the method for forming the aforementioned semiconductor component, the method for forming the second trenches includes performing a patterning process to the substrate and the mask layer.

According to one embodiment of the present invention, in the method for forming the aforementioned semiconductor component, the method for forming the isolation structure material layer includes a chemical vapor deposition process.

According to one embodiment of the present invention, in the method for forming the aforementioned semiconductor component, the method for removing the portion of the isolation structure material layer includes a chemical mechanical polishing process.

According to one embodiment of the present invention, in the method for forming the aforementioned semiconductor component, the method for removing the mask layer includes a wet etching process.

According to one embodiment of the present invention, in the method for forming the aforementioned semiconductor component, the profile adjustment process includes a wet etching process.

According to one embodiment of the invention, in the method for forming the aforementioned semiconductor component, the method for forming the dielectric layer includes a thermal oxidation process.

According to one embodiment of the present invention, in the method for forming the aforementioned semiconductor component, the method for forming the conductor pattern includes the following steps. First, a conductor layer is formed on the substrate and fills the first trench. Next, the portion of the conductor layer excluding the first trench is removed.

According to one embodiment of the present invention, in the method for forming the aforementioned semiconductor component, the method for forming the conductor layer includes a chemical vapor deposition process.

According to one embodiment of the present invention, in the method for forming the aforementioned semiconductor component, the method for removing the portion of the conductor layer includes a chemical mechanical polishing process.

In view of the above, since the included angle formed by the sidewall of the protruding portion of the isolation structure and the surface of the substrate is an obtuse angle, the included angle formed by the sidewall of the conductor pattern and the bottom surface of the conductor pattern is also an obtuse angle. Hence, after the striped conductor pattern is defined as a block floating gate, no conductor material residue is produced, preventing the occurrence of a short circuit between two adjacent block floating gates.

Further, since the method for forming the semiconductor component of the present invention utilizes self-alignment to form the conductor pattern, the number of photo-masks used can thus be reduced, simplifying the fabrication process and lowering the manufacturing costs.

In addition, since the method for forming the semiconductor component of the present invention first forms the trench used for defining an active region and then forms the conductor pattern, the layer to be etched for forming the trench does not need the existence of the conductor layer for forming the conductor pattern that is required by the conventional art such that the active region can be easily defined.

On the other hand, the trench depth to be filled by the isolation structure material is shallower than that of the conventional trench due to the exclusion of the conductor layer (e.g. the polysilicion floating gate material layer 104 shown in FIG. 1A) for forming the conductor pattern (e.g. the floating gate pattern 110 shown in FIG. 1B) utilized by the conventional art. As a result, the gap-filling of the isolation material layer is improved and an isolation structure having high quality and integrity can be formed.

It is to be understood that both the foregoing general description and the following detailed description are exemplary, and are intended to provide further explanation of the invention as claimed.

### BRIEF DESCRIPTION OF THE DRAWINGS

FIGS. 1A through 1C are schematic cross-sectional views illustrating the steps for fabricating a conventional floating gate structure.

FIGS. 2A through 2D are cross-sectional views illustrating a process for fabricating a floating gate structure according to one embodiment of the present invention.

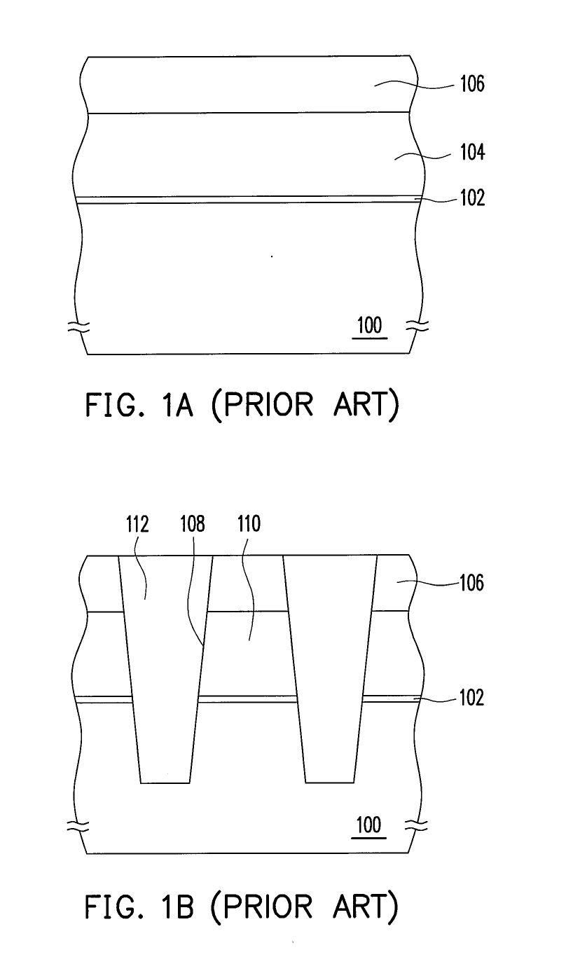

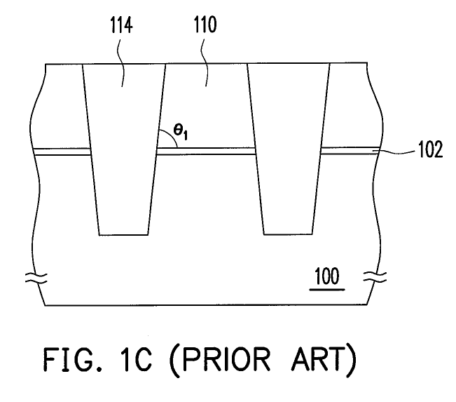

### DESCRIPTION OF EMBODIMENTS

A floating gate structure is used as an example to illustrate the semiconductor component of the present invention and the method for fabricating the same in the following description.

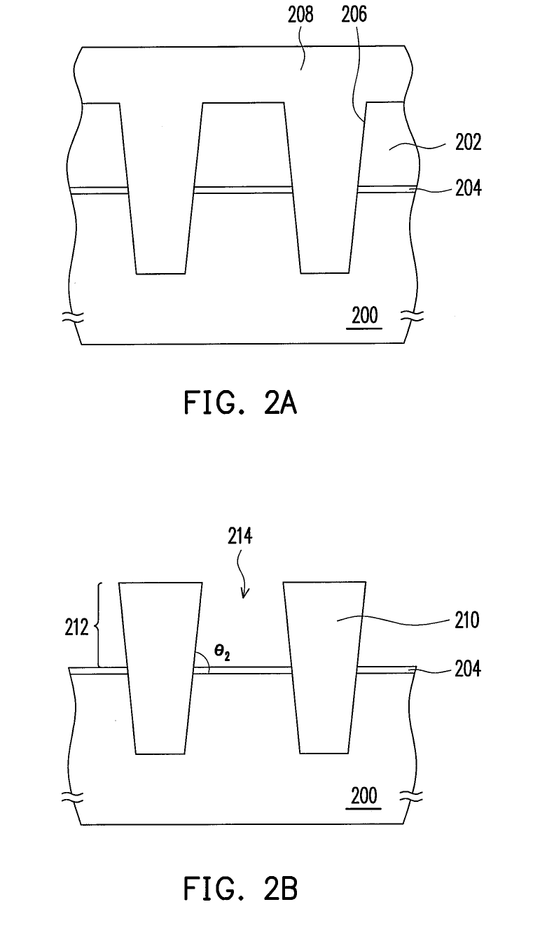

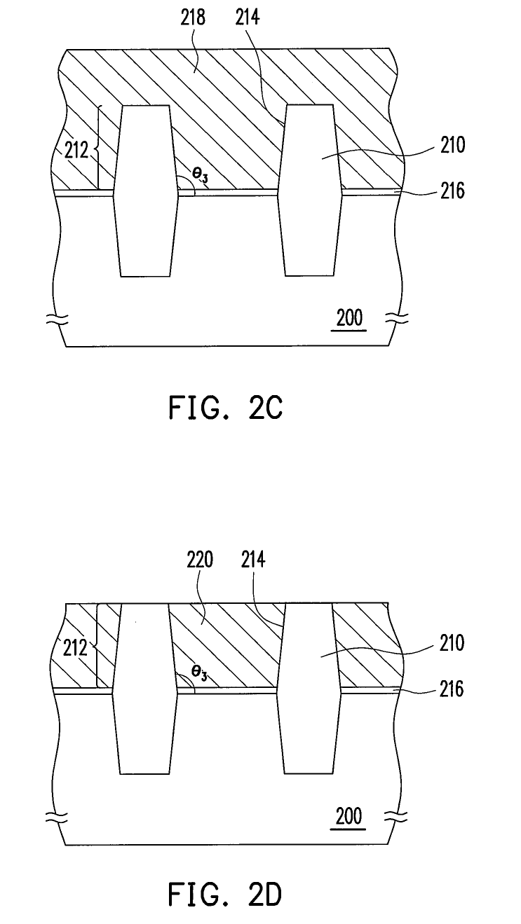

FIGS. 2A through 2D are cross-sectional views illustrating a process for fabricating a floating gate structure according to one embodiment of the present invention.

Referring to FIG. 2A, a mask layer 202 is formed on a substrate 200. The substrate 200 is, for example, a silicon substrate. The material used for fabricating the mask layer 202 is, for example, silicon nitride. The method used for forming the mask layer 202 is, for example, a chemical vapor deposition process.

Further, prior to the formation of the mask layer 202, a pad oxide layer 204 may be selectively formed on the substrate 200. The pad oxide layer 204 can prevent the generation of stress by the mask layer 202 on the substrate 200 and enhance the adhesion between the mask layer 202 and the substrate 200. The method for forming the pad oxide layer 204 is, for example, a thermal oxidation process.

Next, a trench 206 is formed in the substrate 200 and the mask layer 202. The method used for forming the trench 206 includes, for example, performing a patterning process to the substrate 200, the pad oxide layer 204, and the mask layer 202. Further, the patterning process is, for example, a photolithography process.

Thereafter, an isolation structure material layer 208 is formed on the mask layer 202 and fills the trench 206. The material used for forming the isolation structure material layer 208 is, for example, silicon oxide. The method used for forming the insulation structure material layer 208 is, for example, a chemical vapor deposition process.

Referring to FIG. 2B, the isolation structure material layer 208 on top of the mask layer 202 is removed to form an isolation structure 210 in the trench 206 of the substrate 200. The method used for removing the portion of the isolation structure material layer 208 is, for example, a chemical mechanical polishing process using the mask layer 202 as a stop layer. In view of the above, the isolation structure 210 has protruding portions 212 protruding from the surface of the substrate 200 and a trench 214 is formed between two adjacent protruding portions 212. Further, an angle θ₂ formed between a sidewall of the protruding portion 212 and of the surface of the substrate 200 is an acute angle.

Thereafter, the mask layer 202 is removed. The method used for removing the mask layer 202 is, for example, a wet etching process.

Afterwards, referring to FIG. 2C, a profile adjustment process is performed to the protruding portions 212 to modify the angle θ₂ formed between the sidewall of a respective one of the protruding portions 212 and the surface of the substrate 200 to an angle θ₃ and the angle θ₃ is an obtuse angle. The profile adjustment process performed to the protruding portions 212 is, for example, a wet etching process. In the present embodiment, the etchant used includes, for example, hydrofluoric acid (HF).

In addition, to further control the thickness and the quality of the subsequently formed tunneling dielectric layer, the pad oxide layer 204 disposed on the substrate 200 is removed prior to the formation of the tunneling dielectric layer. In the present embodiment, the pad oxide layer 204 is removed, for example, when performing a profile adjustment process to the protruding portions 212.

Further, a dielectric layer 216 is formed on the portion of the substrate 200 exposed by the trench 214, which is used as a tunneling dielectric layer. The material used for forming the dielectric layer 216 is, for example, silicon oxide. The method used for forming the dielectric layer 216 is, for example, a thermal oxidation process.

Thereafter, a conductor layer 218 is formed on the substrate 200. In addition, in another embodiment, the conductor layer 218 fills the trench 214 and is subsequently used as a floating gate. The material used for forming the conductor layer 218 is, for example, polysilicon. The method used for forming the conductor layer 218 is, for example, a chemical vapor deposition process.

Referring to FIG. 2D, the conductor layer 218 excluding the trench 214 is removed using the isolation structure 210 as a stop to form a striped conductor pattern 220 on the dielectric layer 216 and between two adjacent isolation structures 210. Further, in another embodiment, the conductor pattern 220 fills the trench 214. The method used for removing the conductor layer 218 is, for example, a chemical mechanical polishing process.

In view of the above, the conductor pattern 220 is formed by self-alignment, thus the number of photo-masks used is reduced and the manufacturing cost is lowered.

On the other hand, the trench 206 for defining an active region is formed prior to the formation of the conductor pattern 220. Therefore, the layer to be etched for forming the trench 206 does not need the existence of the conductor layer 218 for forming the conductor pattern 220 that is required by the conventional art and the active region can be easily defined.

Further, since the depth of the trench 206 to be filled by the isolation structure material layer 208 is shallower than that of the conventional trench due to the exclusion of the conductor layer 218 for forming the conductor pattern 220 as required by the conventional art, the isolation structure material layer 208 has better gap-filling and forms an isolation structure 210 having high quality and integrity.

In the following description, FIG. 2D is used to illustrate a floating gate structure according to one embodiment of the present invention.

Referring to FIG. 2D, the floating gate structure includes a substrate 200, an isolation structure 210, a dielectric layer 216, and a conductor pattern 220. The isolation structure 210 is disposed in the substrate 200. Further, the isolation structure 210 has protruding portions 212 that protruding from the surface of the substrate 200. In addition, a trench 214 is formed between two adjacent protruding portions 212 and the angle θ₃ formed by the sidewall of a respective one of the protruding portions 212 and the surface of the substrate 200 is an obtuse angle. The conductor pattern 220 is disposed in the trench 214 and fills the trench 214. The material and the method used for forming each component of the floating gate structure of the present invention are described in details in the above embodiments. Hence, a detailed description thereof is omitted.

In view of the foregoing, the angle θ₃ formed between the sidewall of the protruding portion 212 of the isolation structure 210 and the surface of the substrate 200 is an obtuse angle, the angle formed between the sidewall of the conductor pattern 220 and the bottom surface of the conductor pattern 220 is also θ₃. Hence, after the striped conductor pattern 220 is defined as a block conductor pattern, no residues of the conductor layer is generated, and thus prevents the occurrence of a short circuit between two adjacent block conductor patterns.

In summary, the present invention has at least the following advantages:

1. When using the floating gate structure of the present invention, no residue of the conductor material is generated after the striped conductor pattern is defined as a block conductor patter, which prevents the occurrence of a short circuit between two adjacent block conductor patterns.

2. Since the method for forming the floating gate structure according to the present invention utilizes a self-alignment process, the number of photo-masks used is reduced and the manufacturing cost is thus lowered.

3. When using the floating gate structure of the present invention, an active region can be easily defined.

4. The method for forming the floating gate structure according to the present invention can enhance the gap-filling of the isolation structure material layer to form an isolation structure having high quality and integrity.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A semiconductor component, comprising:
a substrate;
two isolation structures disposed in the substrate and each isolation structure having a protruding portion protruding from a surface of the substrate;
a trench formed between two adjacent protruding portions, wherein an angle formed between a sidewall of a respective protruding portion and the surface of the substrate is an obtuse angle; and
a conductor pattern disposed and filled the trench.

2. The semiconductor component of claim 1, wherein the substrate is a silicon substrate.

3. The semiconductor component of claim 1, wherein a material used for forming the isolation structures comprises silicon oxide.

4. The semiconductor component of claim 1, wherein a material used for forming the conductor pattern comprises polysilicon.

5. The semiconductor component of claim 1, wherein the semiconductor further comprises a dielectric layer disposed between the conductor pattern and the substrate.

6. A method for fabricating a semiconductor component, comprising:
forming two isolation structures in a substrate, wherein each of the isolation structures has a protruding portion protruding from a surface of the substrate, a first trench is formed between the protruding portions, and an angle formed by the sidewall of the protruding portion and the surface of the substrate is an acute angle;
performing a profile adjustment process to the protruding portions to modify the acute angle to an obtuse angle; and
forming a conductor pattern on the substrate, wherein the conductor pattern fills the first trench.

7. The method of claim 6, wherein the method used for forming the isolation structures comprises:
forming a mask layer on the substrate;
forming two second trenches in the substrate and the mask layer;
forming an isolation structure material layer on the mask layer, wherein the isolation structure material layer fills the second trenches;
removing a portion of the isolation structure material layer; and
removing the mask layer.

8. The method of claim 7 further comprising forming a dielectric layer on a portion of the substrate which is exposed by the first trench.

9. The method of claim 7, wherein the method used for forming the mask layer comprises a chemical vapor deposition process.

10. The method of claim 7, wherein the method used for forming the second trenches comprises performing a patterning process to the substrate and the mask layer.

11. The method of claim 7, wherein the method used for forming the isolation structure material layer comprises a chemical vapor deposition process.

12. The method of claim 7, wherein the method used for removing the portion of the isolation structure material layer comprises a chemical mechanical polishing process.

13. The method of claim 7, wherein the method used for removing the mask layer comprises a wet etching process.

14. The method of claim 6, wherein the profile adjustment process comprises a wet etching process.

15. The method of claim 8, wherein the method used for forming the dielectric layer comprises a thermal oxidation process.

16. The method of claim 7, wherein the method used for forming the conductor pattern comprises:
forming a conductor layer on the substrate, wherein the first conductor layer fills the first trench; and
removing a portion of the conductor layer.

17. The method of claim 8, wherein the method used for forming the conductor pattern comprises:
forming a conductor layer on the substrate, wherein the first conductor layer fills the first trench; and
removing a portion of the conductor layer.

18. The method of claim 17, wherein the method used for forming the conductor layer comprises a chemical vapor deposition process.

19. The method of claim 16, wherein the method used for removing the portion of the isolation structure material layer comprises a chemical mechanical polishing process.
